(19) United States
(12) Patent Application Publication
(10) Pub. No.: US 2017/0031394 A1
(43) Pub. Date: Feb. 2, 2017

(54) A HEAT-DISSIPATING DEVICE INCLUDING A VAPOR CHAMBER AND A RADIAL FIN ASSEMBLY

(71) Applicant: HEWLETT-PACKARD DEVELOPMENT COMPANY, L.P., HOUSTON, TX (US)

(72) Inventors: CHIENLUNG YANG, HOUSTON, TX (US); HUI LENG LIM, HOUSTON, TX (US); KUAN-TING WU, TAIPEI CITY (TW)

(21) Appl. No.: 15/303,543

(22) PCT Filed: Apr. 28, 2014
(86) PCT No.: PCT/US2014/035616

§ 371 Date: Oct. 12, 2016

(51) Int. Cl. G06F 1/20; F04D 17/16; F04D 29/44; H05K 7/20

(52) U.S. Cl. CPC G06F 1/20; H05K 7/20336; H05K 7/20145; F04D 17/16; F04D 29/441

(57) ABSTRACT

A vapor chamber to thermally contact a heat-producing component includes an opening. An airflow generator is at least partially mounted in the opening of the vapor chamber. A radial fin assembly extends at least partially around the airflow generator.

### BACKGROUND

An electronic device can include various electronic components, such a processor, an input/output (I/O) component, a memory component, a storage component, and so forth. The electronic components can generate heat during operation.

A heat-dissipating device can be employed to dissipate heat produced by an electronic component. The heat-dissipating device can be thermal contacted to the electronic component to conduct heat away from the electronic component.

### BRIEF DESCRIPTION OF THE DRAWINGS

Some implementations a described with respect to the following figures.

FIG. 1 is a schematic top view of a heat-dissipating device according to some implementations.

FIG. 2 is a schematic top view of a vapor chamber in a heat dissipating device according to some implementations.

FIG. 3 is a cross-sectional view of a portion of a vapor chamber useable in a heat-dissipating device according to some implementations.

FIG. 4 is a schematic top view of a heat-dissipating device thermally contacted to a heat-producing component, in accordance with some implementations.

FIG. 5 is a schematic top view of a heat-dissipating device according to alternative implementations.

FIG. 6 is a perspective view of a heat-dissipating device according to alternative implementations.

FIG. 7 is a flow diagram of a process of forming a heat-dissipating device according to some implementations.

### DETAILED DESCRIPTION

When a heat-dissipating device is thermally contacted to an electronic component, heat can be conducted from the electronic component to surface areas of the heat-dissipating device that are exposed to airflow. Such surface areas can be surface areas of fins of the heat-dissipating device. Airflow through the flow channels between the fins can carry heat away from the fins.

As electronic devices (e.g. notebook computers, tablet computers, smart phones, personal digital assistants, mobile phones, etc.) continue to decrease in size, it can be challenging to fit heat-dissipating devices with sufficient heat dissipation capability into the electronic devices. Reducing the size of a heat-dissipating device may reduce its heat dissipation capability such that the heat dissipating device no longer is able to adequately cool an electronic component in the electronic device. Insufficient heat dissipation can lead to overheating of the electronic device, which can cause damage to the electronic device.

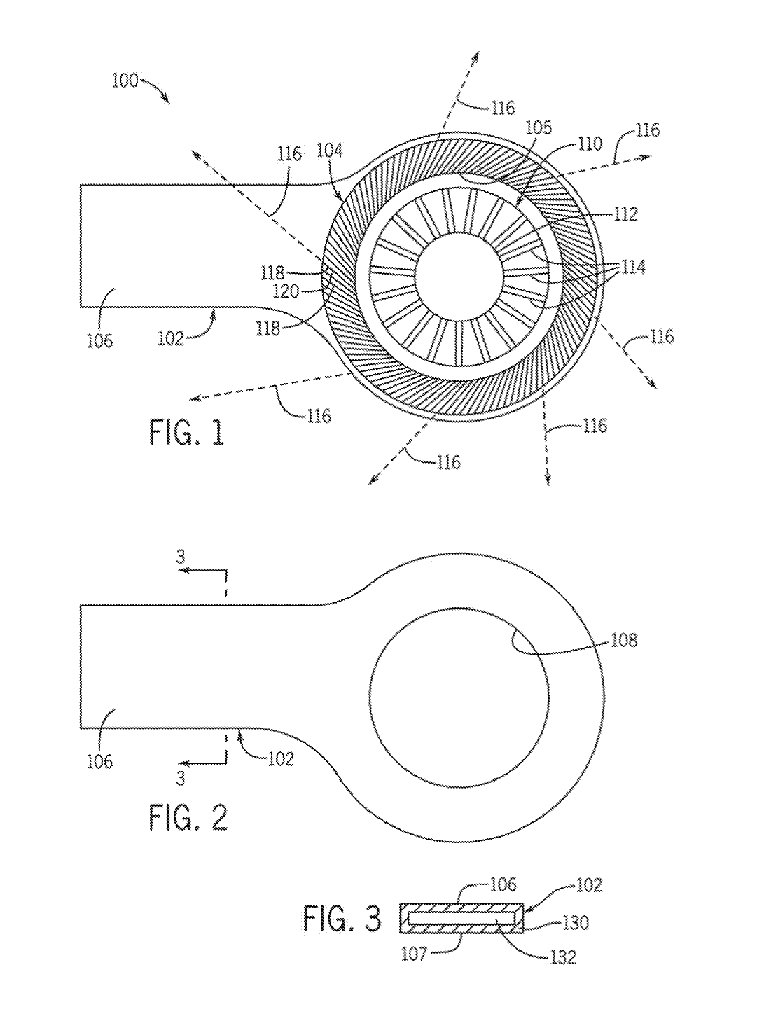

In accordance with some implementations, as shown in FIG. 1, a heat-dissipating device 100 includes a vapor chamber 102, a radial fin assembly 104, and an airflow generator 110. FIG. 2 shows the vapor chamber 102, without the radial fin assembly 104 and the airflow generator 110 of FIG. 1. FIG. 3 is a cross-sectional view of the vapor chamber 102 along section 3-3 in FIG. 2.

As shown in FIG. 3, the vapor chamber 102 has a housing 130 that defines an inner space 132 in which fluid is provided. The housing 130 of the vapor chamber 102 can be formed of a thermally conductive material, such as copper, aluminum, and so forth. The housing 130 of the vapor chamber 102 is a sealed housing that prevents the fluid inside the inner space 132 from escaping. Although not shown, the inner space 132 of the vapor chamber 102 includes a wick structure for communicating fluid along the vapor chamber 102. The fluid in the inner space 132 carries heat from a first location of the vapor chamber 102 (the first location can be proximate a heat-producing component) to a second location of the vapor chamber 102 (the second location can be proximate a heat-dissipation element such as the radial fin assembly 104 in FIG. 1). The fluid in the inner space 132 can flow in a generally horizontal or vertical (or both) direction from the first location to the second location (the first location and second location of the vapor chamber 102 are horizontally and/or vertically spaced from each other).

The housing 130 of the vapor chamber 102 provides an upper planar upper surface 106 and a lower planar surface 107, as shown in FIGS. 1-3. The upper and lower planar surfaces 106 and 107 are on opposite sides of the housing 130.

In addition, the housing 130 of the vapor chamber 102 includes a opening 108 (FIG. 2) to receive the airflow generator 10. Note also that the radial fin assembly 104 also has an inner opening 105 to receive the airflow generator 110. The inner opening 105 of the radial fin assembly 104 can be larger than the opening 108 of the vapor chamber 102.

As further shown in FIG. 1, the radial fin assembly 104 can be mounted on the upper planar surface 106 of the vapor chamber 102. The upper planar surface 106 has an area that is sufficiently large to accommodate an entirety of the radial fin assembly 104. The radial fin assembly 104 is thermally contacted to the upper planar surface 106 of the vapor chamber 102, either directly or through a thermally conductive layer. The radial fin assembly can extend around the opening 108 of the vapor chamber 102, as shown in FIG. 1.

In an alternative arrangement, the radial fin assembly 104 can be mounted to the lower planar surface 107 of the vapor chamber 102.

Although not shown in FIG. 1, a heat-producing component can also be thermally contacted to the planar surface 106 or 107 of the vapor chamber 102. As another example, heat-producing component can be thermally contacted to both the planar surfaces 106 and 107 of the vapor chamber 102.

The airflow generator 110 can be at least partially mounted in the opening 108 of the vapor chamber 102. Although not shown, the airflow generator 110 can include attachment mechanisms (e.g. attachment tabs and screws) to attach the airflow generator 110 to the vapor chamber 102 The airflow generator 110 can be a blower that includes a rotatable wheel 112 with blades 114 attached to the outer circumference of the wheel 112. Rotation of the wheel 112 and the blades 114 draws cooling air from above and below the vapor chamber 102, and propels the drawn air outwardly in radial directions indicated by arrows 116.

Placing the airflow generator 110 in the opening 108 allows air to be drawn into the airflow generator 110 along directions that are generally perpendicular to the planar surface 106 or 107 of the vapor chamber 102. The ability to draw air from both above and below the vapor chamber 102 can increase the amount of cooling airflow produced by the airflow generator 110.

The outlet directions of airflow can extend 360° around the circumference of the radial fin assembly 104, which can improve cooling performance of the heat dissipating device 100. Also, with the ability to draw cooling air from either above or below the heat-dissipating device 100, and the ability to direct airflow in many directions around the circumference of the radial fin assembly 104, flexibility in use of the heat-dissipating device 100 is increased. The heat-dissipating device 100 can be used in any one of multiple layouts of components in an electronic device.

The radial fin assembly 104 includes radially arranged fins 118 that extend around the circumference of the radial fin assembly 104. The fins 118 of the radial fin assembly 104 can be formed of a thermally conductive material, such as copper, aluminum, and so forth.

The radially arranged fins 118 form flow channels 120 between successive pairs of the fins 118. The flow channels 120 extend generally in the radial direction of the radial fin assembly 104, such that air propelled outwardly by the air generator 110 can pass through the flow channels 120 in the radial directions 116.

More generally, a “radial fin assembly” can refer to an assembly of fins or other types of heat dissipating structures) that define flow channels to allow airflow in a direction (e.g. direction 116) that is generally perpendicular to the direction along which air is drawn by the airflow generator 110.

At least partially mounting the air generator 110 in the opening 108 of the vapor chamber 102 can also reduce the overall thickness of the heat-dissipating device 100, such that a heat-dissipating device with a thinner profile can be provided. The heat-dissipating device 100 with a thinner profile can be useful in an electronic device that has a small amount of space within a housing of the electronic device.

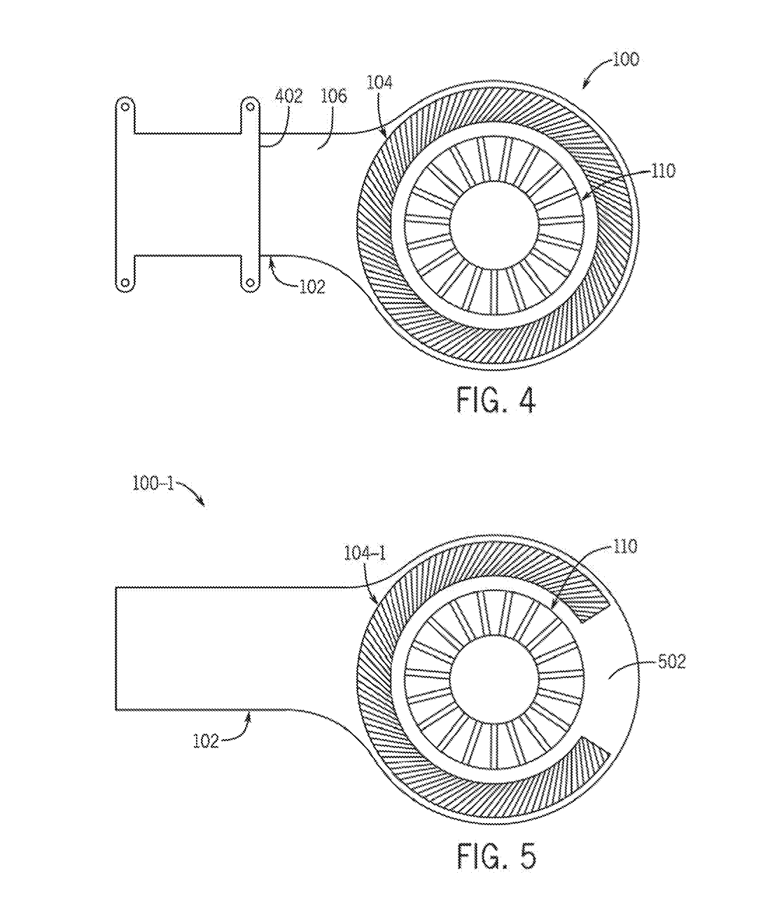

FIG. 4 shows a heat-producing component 402 mounted to the upper planar surface 106 of the vapor chamber 102. Alternatively, the heat-producing component 402 can be mounted to the lower planar surface 107 of the vapor chamber 102. The heat-producing component 402 can be thermally contacted to the surface 106 or 107, either directly or through a thermally conductive layer.

Examples of the heat-producing component 402 can include any of the following: a processor, an input/output (I/O) component, a memory component, a storage component, and so forth. Alternatively, the heat-producing component 402 can be a heat sink, which is in turn thermally contacted to an electronic component that produces heat during operation of the electronic component.

In the FIG. 1 example, the radial fin assembly 104 has a profile (when viewed from the top or bottom of the radial fin assembly 104) that is generally circular in shape. In other examples, the profile of the radial fin assembly 104 can have a different shape, including an elliptical shape, a polygonal shape or an irregular shape. Also, the heat fin assembly 104 does not have to fully encircle the air generator 110 and the opening 108 of the vapor chamber 102. For example, as shown in FIG. 5, a heat-dissipating device 100-1 according to alternative implementations can employ a heat fin assembly 104-1 that has a profile that is semi-circular in shape. In other words, the profile of the heat fin assembly 104-1 does not fully extend around a circle, but just partially around the circle, leaving a gap 502 without any fins.

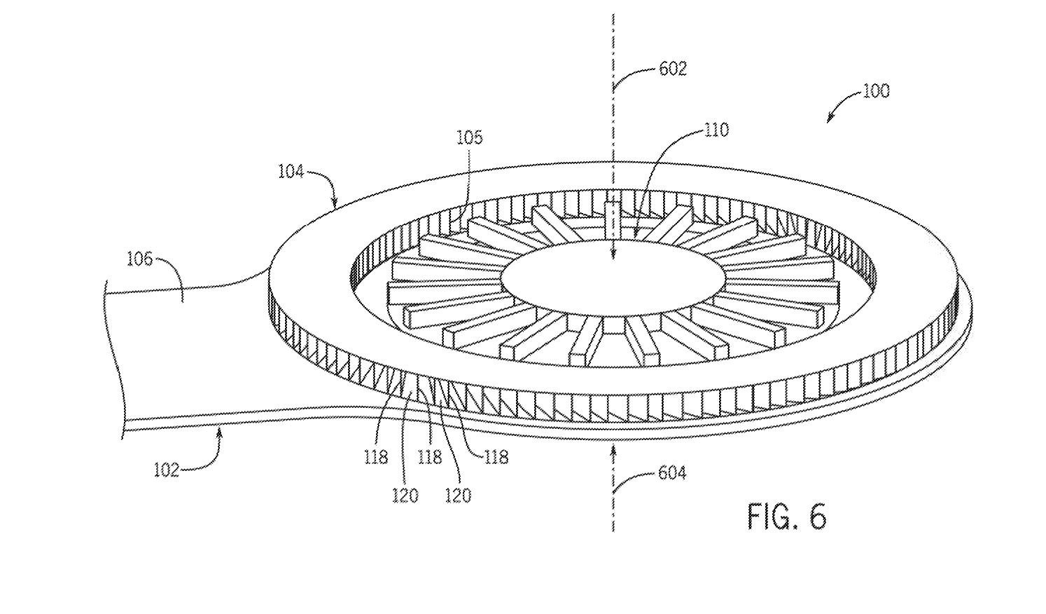

FIG. 6 is a perspective view of the heat-dissipating device 100 according to some implementations. As shown in FIG. 6, cooling air is drawn from above and below the vapor chamber 102, in directions depicted by arrows 602 and 604. The directions 602 and 604 are generally perpendicular to the planar surface 106 of the vapor chamber 102. The airflow generator 110 draws the cooling air into the inner opening 105 of the radial fin assembly 104 along directions 602 and 604, and directs the cooling air in radial directions 116 (FIG. 1) through the flow channels 120 between the fins 118 of the radial fin assembly 104. The radial directions 116 are generally parallel to the planar surface 106 of the vapor chamber 102 and generally perpendicular to the directions 602 and 604 of cooling air drawn by the airflow generator 110.

Using a heat-dissipating device according to some implementations, the inlet direction (602 and/or 604) of the cooling air is generally perpendicular to the outlet directions 116 of air directed by the airflow generator 110. With the arrangement shown in FIG. 6, efficiency of the heat-dissipating device 100 is increased since there is reduced resistance to airflow produced by the airflow generator 110. The arrangement shown in FIG. 6 does not include an airflow obstructing element that can potentially obstruct the flow of air in the inlet directions 602, 604 or outlet directions 116.

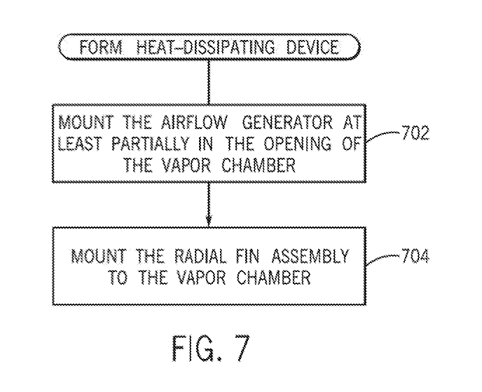

FIG. 7 is a flow diagram of a process of forming a heat-dissipating device (e.g. 100 or 100-1), according to some implementations. The process includes mounting (at 702) the airflow generator 110 at least partially in the opening 108 of the housing 130 of the vapor chamber 102. The process further includes mounting (at 704) the radial fin assembly (e.g. 104 or 104-1) to the vapor chamber 102.

Once assembled, the heat-dissipating device can be installed into an electronic device. The heat-dissipating device can be thermally contacted to a heat-producing component (e.g. 402 in FIG. 4), Heat produced by the heat-producing component causes a liquid in the inner space 132 of the vapor chamber 102 to vaporize. The heated vapor flows from a first location of the vapor chamber 102 (that is in thermal contact with the heat-producing component) to a second location of the vapor chamber 102 (that is in thermal contact with the radial fin assembly (e.g. 104 or 104-1). The heated vapor cooled by the radial fin assembly transitions back to a liquid, which then flows back to the first location of the vapor chamber 102.

In the foregoing description, numerous details are set forth to provide an understanding of the subject disclosed herein. However, implementations may be practiced without some of these details. Other implementations may include modifications and variations from the details discussed above. It is intended that appended claims cover such modifications and variations.

What is claimed is:

1. A heat-dissipating device comprising:
a vapor chamber to thermally contact a heat producing component, the vapor chamber including an opening;
an airflow generator at least partially mounted in the opening of the vapor chamber; and
a radial fin assembly extending at least partially around the airflow generator, the radial fin assembly including fins and flow channels between the fins for passing airflow generated by the airflow generator.

2. The heat-dissipating device of claim 1, wherein the radial fin assembly includes an opening to receive the airflow generator.

3. The heat-dissipating device of claim 2, wherein the vapor chamber includes a housing. the radial fin assembly in thermal contact with the housing.

4. The heat-dissipating device of claim 3, wherein the housing is to thermally contact the heat-producing component.

5. The heat-dissipating device of claim 1, wherein the fins and the flow channels between the fins are arranged radially to allow the airflow to flow in radial directions.

6. The heat-dissipating device of claim 5, wherein the airflow generator is arranged to draw cooling air from above and below the airflow generator, and to direct the drawn cooling air through the flow channels in the radial directions.

7. The heat-dissipating device of claim 1, wherein the vapor chamber contains a fluid to carry heat from a first location for thermally contacting the heat-producing component, to a second location of the vapor chamber in thermal contact with the radial fin assembly.

8. The heat-dissipating device of claim 1, wherein a profile of the radial fin assembly is one of a circular shape a semi-circular shape, an elliptical shape, polygonal shape.

9. The heat-dissipating device of claim wherein the airflow generator comprises a blower.

10. The heat-dissipating device of claim 1, wherein the vapor chamber includes a housing providing a planar surface on which the radial fin assembly is mounted.

11. A method of forming a heat-dissipating device, comprising:
mounting a blower at least partially in an opening of a vapor chamber that is for thermally contacting a heat-producing component, the vapor chamber including a housing containing a fluid to carry heat; and
mounting a radial fin assembly to the vapor chamber, the radial fin assembly including radial fins and flow channels between the radial fins, wherein airflow generated by the blower is to pass in radial directions through the flow channels.

12. The method of claim 11, further comprising receiving the blower in an opening of the radial fin assembly.

13. The method of claim 11, wherein a first location of the vapor chamber in thermal contact with the radial fin assembly is spaced apart from a second location of the vapor chamber for thermally contacting the heat-producing component.

14. A vapor chamber comprising:
a housing defining an inner space that contains a fluid for carrying heat from a first location of the vapor chamber to a second location of the vapor chamber; and
an opening formed in the housing to receive an airflow generator, the opening allowing the airflow generator to draw cooling air from above and below the vapor chamber, and to direct the cooling air outwardly in radial directions through flow channels between fins of a radial fin assembly.

15. The vapor chamber of claim 14, wherein the housing provide a planar surface on which the radial fin assembly is mountable.
